(19) United States
(12) Patent Application Publication
(10) Pub. No.: US 2020/0201954 A1
(43) Pub. Date: Jun. 25, 2020

(54) METHOD OF DESIGNING A LAYOUT FOR A SEMICONDUCTOR INTEGRATED CIRCUIT

(71) Applicant: Samsung Electronics Co., Ltd., Suwon-si (KR)

(72) Inventors: Vassilios Gerousis, Georgetown, TX (US); Rwik Sengupta, Austin, TX (US)

(21) Appl. No.: 16/366,916

(22) Filed: Mar. 27, 2019

Related U.S. Application Data
(60) Provisional application No. 62/784,328, filed on Dec. 21, 2018.

(51) Int. Cl. G06F 17/50; H01L 27/02

(52) U.S. Cl. CPC G06F 17/5072; H01L 27/0207; G06F 17/5081; G06F 17/5077

(57) ABSTRACT

A computer-implemented method includes generating a layout of a semiconductor cell. The layout includes a series of semiconductor devices, intra-cell connections, including power rails, between the plurality of semiconductor devices, and a series of shadow pin regions for placement of a series of pins by a placement and routing tool. Each shadow pin region of the series of shadow pin regions defines a maximum legal boundary that each pin of the series of pins may occupy without violating ground rules.

### CROSS-REFERENCE TO RELATED APPLICATION(S)

The present application claims priority to and the benefit of U.S. Provisional Application No. 62/784,328, filed Dec. 21, 2018, the entire contents of which are incorporated herein by reference.

### BACKGROUND

### 1. Field

The present disclosure relates generally to methods of designing a layout of a semiconductor cell and a semiconductor integrated circuit.

### 2. Description of Related Art

Electronic design automation (EDA) is a tool utilized to design semiconductor integrated circuits. During the process of designing the semiconductor integrated circuit, a designer selects from a library of pre-defined and verified cells to use as building blocks for the semiconductor integrated circuit. These cells selected from the library may then be arranged and interconnected to achieve the desired functionality of the semiconductor integrated circuit.

Related art methods of designing layouts for semiconductor cells include defining fixed locations and shapes of the pins in the middle-of-line (MOL) of the cell. However, fixed pin definitions reduce flexibility in routing and reduce accessibility of the pins, which are impediments to higher utilization rates and block level scaling.

### SUMMARY

The present disclosure is directed to various methods of designing a layout for semiconductor cells and semiconductor integrated circuits. In one embodiment, the method includes generating a layout of a semiconductor cell. The layout includes a series of semiconductor devices, intra-cell connections, including power rails, between the series of semiconductor devices, and a series of shadow pin regions for placement of a series of pins by a placement and routing tool. Each shadow pin region of the series of shadow pin regions defining a maximum legal boundary that each pin of the series of pins may occupy without violating ground rules.

The layout may also include the series of pins in the series of shadow pin regions. The series of pins may be placed by the placement and routing tool.

The layout may also include a series of access vias on the series of pins. The series of access vias may be placed by the placement and routing tool.

The method may also include generating a layout of a semiconductor integrated circuit. The layout of the semiconductor integrated circuit includes a series of instances of the semiconductor cell, and routing metal layers connected to the series of pins by the series of access vias. The routing metal layers may be placed with the placement and routing tool.

At least one pin of the series of pins may be smaller than a corresponding shadow pin region of the series of shadow pin regions.

At least one pin of the series of pins may be substantially a same size as a corresponding shadow pin region of the series of shadow pin regions.

The series of shadow pin regions may be on a routing grid.

The series of shadow pin regions may not be on a routing grid.

The layout may also include at least one blockage region.

At least one shadow pin region of the series of shadow pin regions may be a 1D structure.

At least one shadow pin region of the series of shadow pin regions may be a 2, D structure.

The series of shadow pin regions may be associated with a metal layer of the semiconductor cell such as metal layer Mint, metal layer M0, metal layer M1, or metal layer M2.

The layout may also include power staples or power stripes.

The power staples may include a pair of double power staples.

At least two pins of the series of pins may be aligned.

At least two pins of the series of pins may be staggered.

The present disclosure is also directed to various embodiments of a non-transitory computer readable medium having instructions stored therein which, when executed by a processor, cause the processor to generate a layout for a semiconductor cell. The layout includes a series of semiconductor devices, intra-cell connections, including power rails, between the series of semiconductor devices, and a series of shadow pin regions for placement of a plurality of pins by a placement and routing tool. Each shadow pin region of the series of shadow pin regions defines a maximum legal boundary that each pin of the series of pins may occupy without violating ground rules.

The instructions, when executed by the processor, may further cause the processor to place the series of pins within the shadow pin regions.

The instructions, when executed by the processor, may further cause the processor to generate a layout for a semiconductor integrated circuit including a series of instances of the semiconductor cell and interconnections between the series of instances of the semiconductor cell.

This summary is provided to introduce a selection of concepts that are further described below in the detailed description. This summary is not intended to identify key or essential features of the claimed subject matter, nor is it intended to be used in limiting the scope of the claimed subject matter. One or more of the described features may be combined with one or more other described features to provide a workable device.

### BRIEF DESCRIPTION OF THE DRAWINGS

The features and advantages of embodiments of the present disclosure will be better understood by reference to the following detailed description when considered in conjunction with the accompanying figures. In the figures, like reference numerals are used throughout the figures to reference like features and components. The figures are not necessarily drawn to scale.

FIG. 1 is a flowchart illustrating tasks of a method of producing a layout for a semiconductor cell and a semiconductor integrated circuit according to one embodiment of the present disclosure;

FIG. 2 is a schematic layout illustrating shadow pin layers and connecting vias produced during one task of the method illustrated in FIG. 1;

FIG. 3 is a schematic layout illustrating pins produced in the shadow pin layers by a placement and routing (PnR) tool during one task of the method illustrated in FIG. 1;

FIGS. 4A-4B depict a schematic layout illustrating metal routing layers placed over the connecting vias according to one task of the method illustrated in FIG. 1; and

FIG. 5 is a schematic layout illustrating power staples produced during one task of the method illustrated in FIG. 1.

### DETAILED DESCRIPTION

The present disclosure is directed to various embodiments of methods for designing a layout for semiconductor cells and semiconductor integrated circuits that may be utilized to manufacture the semiconductor cells and semiconductor integrated circuits. The methods according to various embodiments of the present disclosure include defining a series of shadow pin regions in which a series of pins may be placed by a placement and routing (PnR) tool. Each of the shadow pin regions defines a maximum legal boundary that each of the pins may occupy without violating ground rules (i.e., the shadow pin regions define the entire extent of legal pin positions). Accordingly, the shadow pin regions define multiple permissible locations for the pins, rather than a fixed shape and location for the pins. Defining shadow pin regions enables the PnR tool to define pins as needed, which improves pin access and the performance, power, and area (PPA) metrics of the semiconductor cells and integrated circuits. Additionally, defining shadow pin regions provides the freedom for the PnR tool to place cells without any constraints.

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

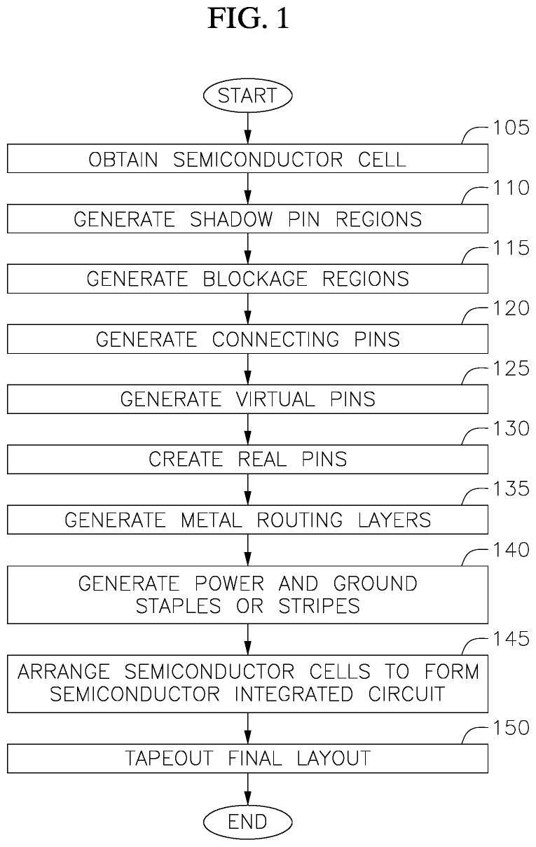

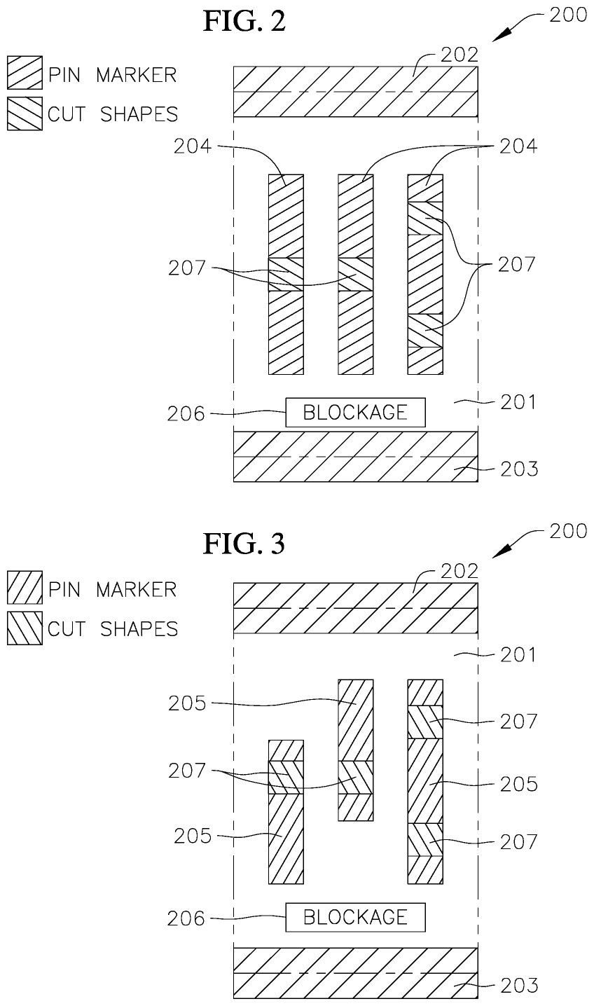

FIG. 1 illustrates tasks of a method 100 of producing a layout for a semiconductor cell 200 and a semiconductor integrated circuit according to one embodiment of the present disclosure. FIGS. 2-4 illustrate schematic layouts of the semiconductor cell 200 produced during the method 100 illustrated in FIG. 1.

In the embodiment illustrated in FIGS. 1-2, the method 100 includes a task 105 of obtaining a semiconductor cell 200 including semiconductor devices 201 (e.g., an inverter, a NAND gate, a NOR gate, a flip flop, or other logic circuits) and power rails 202, 203 (e.g., Vdd and Vss) overlapping edges of the semiconductor devices 201. The semiconductor cell 200 may be obtained from a library containing a series of different semiconductor cells (e.g., the semiconductor cell 200 may be obtained from a standard cell library containing semiconductor cells having different configurations of the semiconductor devices).

In the embodiment illustrated in FIGS. 1-2, the method 100 also includes a task 110 of generating a series of shadow pin regions 204 (i.e., placeholder pin regions) on the semiconductor devices 201 of the semiconductor cell 200. The shadow pin regions 204 define regions for the placement of a plurality of pins 205 by a placement and routing (PnR) tool in a subsequent task (i.e., the PnR tool is configured to recognize the shadow pin regions 204 as legal pin positions). In one or more embodiments, each of the shadow pin regions 204 defines a maximum legal boundary or substantially a maximum legal boundary that each pin of the plurality of pins 205 may occupy without violating ground rules. Accordingly, the shadow pin regions 204 define multiple permissible locations for the pins 205, rather than a fixed shape and location for the pins 205. The shadow pin regions 204 are configured to enable connection to a routing metal layer with vias dropped by the PnR tool in a subsequent task.

As used herein, the term “pins” refers to the metal wires within the semiconductor cell 200 that define connection points for external connections to the semiconductor cell 200 (e.g., inter-cell connections between the semiconductor cell 200 and another semiconductor cell 200). Additionally, the pins 205 may be output pins (e.g., connection points for output signals of the semiconductor cells 200), input pins (e.g., connection points for input signals of the semiconductor cell 200), or a combination of input and output pins.

In one or more embodiments, one or more of the shadow pin regions 204 may be a 1D structure (e.g., one or more of the shadow pin regions 204 may be rectangular). In one or more embodiments, one or more of the shadow pin regions 204 may be a 2D structure. In one or more embodiments, the shadow pin regions 204 may be a combination of 1D and 2D structures. Additionally, in one or more embodiments, the task 110 may include orienting the shadow pin regions 204 on a routing grid. In one or more embodiments, the task 120 may include orienting the shadow pin regions 204 off the routing grid. The term “routing grid” refers to a grid on which objects of the semiconductor cell 200 are aligned to, and, according to one or more embodiments, may refer to the finest granularity that can be achieved during a manufacturing process for producing the semiconductor cell 200 and the semiconductor integrated circuit. In one or more embodiments, the shadow pin regions 204 may be vertical and/or horizontal.

In one or more embodiments, the shadow pin regions 204 may be defined in a marker layer corresponding to any desired metal layer of the semiconductor cell 200, such as, for example, metal layer Mint, metal layer MO, metal layer M1, or metal layer M2. In one or more embodiments, the shadow pin regions 204 may be defined in a marker layer corresponding to any desired middle-of-line (MOL) layer of the semiconductor cell 200. For instance, in one or more embodiments, the shadow pin regions 204 may correspond to an MOL layer defining source, drain, and gate contacts of the semiconductor device 200.

In the illustrated embodiment, the method 100 also includes a task 115 of defining one or more blockage regions 206 defining obstructions. In the illustrated embodiment, the one or more blockage regions 206 are defined in the same layer as the shadow pin regions 204. The blockage regions 206 define areas in which shadow pin regions 204, and thus the pins 205, cannot be placed.

In the illustrated embodiment, the method 100 also includes a task 120 of defining connecting vias 207 (i.e., pin access vias) overlapping the shadow pin regions 204. The connecting vias 207 define the locations of vias that enable connection between the pins 205, which are placed by the PnR tool during a subsequent task, and metal routing layers, also placed by the PnR tool during a subsequent task of the method. In one or more embodiments, because the shadow pin regions 204 define the legal locations for placement of the pins 205, the PnR tool can place the connecting vias 207 without checking for ground rule violations for actuator middle-of-line (MOL) shapes and layers. Thus, the quality of the PnR tool improves because there are no added restrictions due to the complexity of the MOL layers.

In the embodiment illustrated in FIGS. 1 and 3, the method 100 includes a task 125 of defining “virtual” pins, with the PnR tool, within the shadow pin regions 204 defined in task 110. In the illustrated embodiment, the virtual pins may be inserted only into the shadow pin regions 204 defined in task 110. Additionally, in one or more embodiments, the task 150 of defining the virtual pins may include not placing a virtual pin in one or more of the shadow pin regions 204. The PnR tool is configured to place the virtual pins within the shadow pin regions 204 based on a series of ground rule restrictions, including the minimum area to place a ground rule clean pin within the shadow pin region 204. Additionally, in the illustrated embodiment, the task 125 of defining the virtual pins includes positioning the virtual pins such that the virtual pins overlap the connecting vias 207 determined in task 140 (i.e., the PnR tool is constrained to place the virtual pins within the shadow pin regions 204 and over the connecting vias 207). The task 125 of defining the virtual pins includes positioning the virtual pins such that the virtual pins do not block other pin access on the same semiconductor cell or semiconductor cells placed nearby. Additionally, the task 125 of defining the virtual pins includes locating the virtual pins such that the semiconductor cells can be routed without creating design rule conflict in the semiconductor cell or other semiconductor cells nearby. Furthermore, the task 125 of defining the virtual pins includes locating the virtual pins within the shadow pin regions 204 such that the virtual pins do not violate ground rule with respect to other routing metal shapes.

In the illustrated embodiment, the method 100 also includes a task 130 of creating, by the PnR tool, mask-level metal shapes from the virtual pins defined in task 125 (i.e., creating real pins 205 from the virtual pins). The task 130 of creating the real pins 205 includes ensuring that the real pins 205 do not violate ground design rules (e.g., the task 130 avoids design rules violations of the real pin 205 shapes to other shapes on the same layer).

The size of the pins 205 may be smaller than or equal to the size of the corresponding shadow pin regions 204. In the embodiment illustrated in FIG. 3, the leftmost pin 205 and the center pin 205 are smaller than corresponding leftmost shadow pin region 204 and the center shadow pin region 204, respectively, illustrated in FIG. 2. Additionally, in the embodiment illustrated in FIG. 3, the rightmost pin 205 is equal or substantially equal to the size of the rightmost shadow pin region 204 illustrated in FIG. 2. Accordingly, in one or more embodiments, the task 130 may include defining a combination of one or more pins 205 that are smaller than the corresponding shadow pin regions 204 and one or more pins 205 that are equal or substantially equal in size to the corresponding shadow pin regions 204. Furthermore, in one or more embodiments, the task 130 of defining the pins 205 may include defining two or more pins 205 that are aligned with each other. In one or more embodiments, the task 130 of defining the pins 205 may include defining two or more pins 205 that are staggered relative to each other. In one or more embodiments, the task 130 of defining the pins 205 may include defining a combination of aligned pins and staggered pins. In one or more embodiments, the method 100 may include a task of redefining the locations of the pins iteratively in congested areas to improve routing quality of results (QoR).

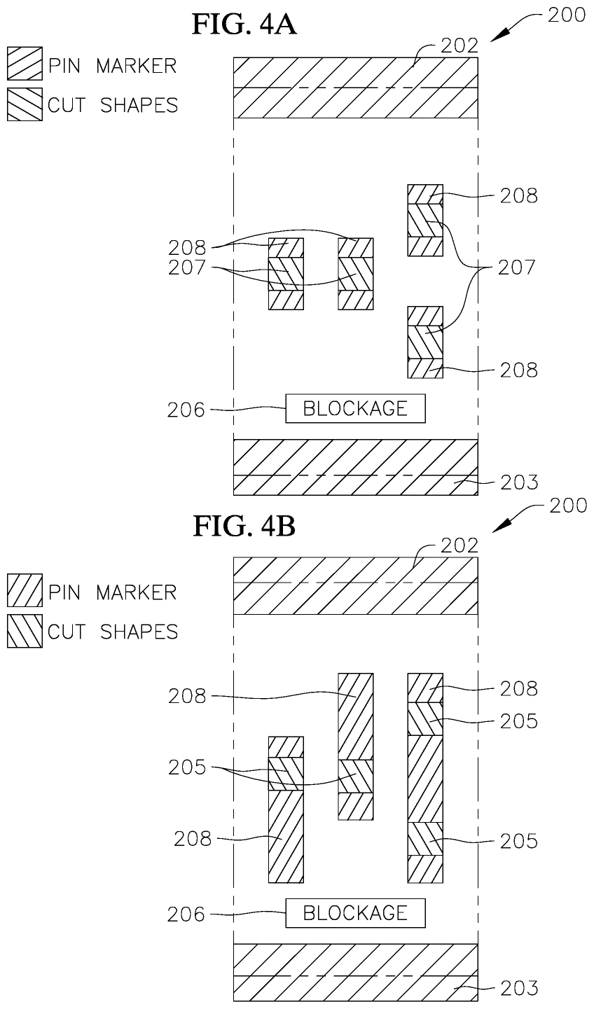

In the embodiment illustrated in FIGS. 1 and 4A, the method 100 also includes a task 135 of defining metal routing layers 208 on the connecting vias 207 to make connections to the connecting vias 207 in a ground rule clean manner. The task 135 of defining the metal routing layers 210 may be performed by any suitable algorithms known in the art.

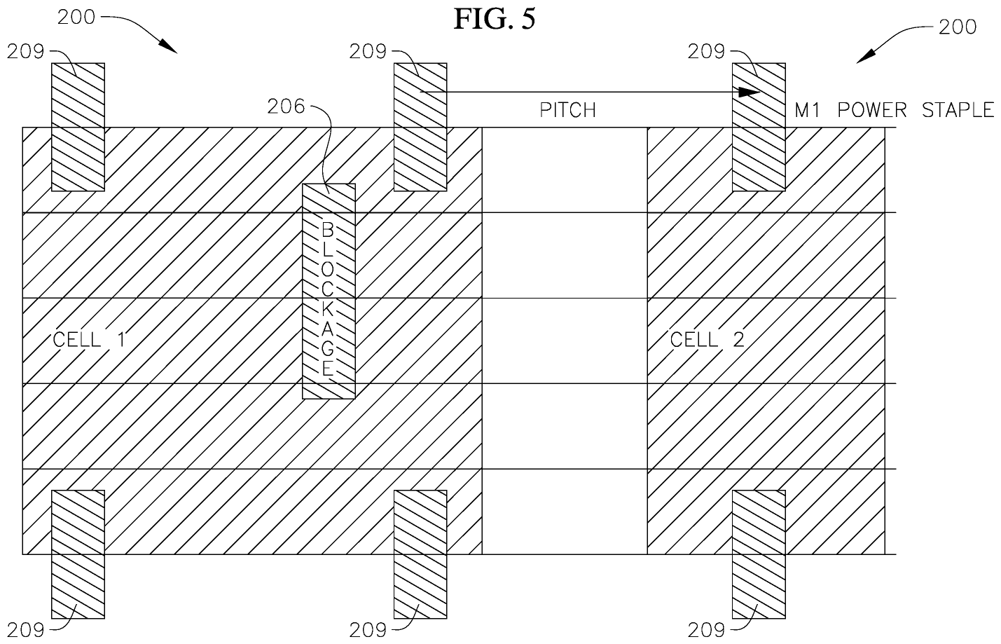

In the embodiment illustrated in FIGS. 1 and 5, the method 100 includes a task 140 of defining one or more power and ground staples or stripes 209. In one or more embodiments, the task 180 may include defining one or more pairs of double power staples 209. The power and ground staples or stripes 209 are regions in which power staples or power stripes may be added depending on the desired power suitable for the intended application. The task 140 of defining power and ground staples or stripes 209 may be added prior to the placement of the semiconductor cell within the semiconductor integrated circuit. In one or more embodiments, the power and ground staples or stripes 211 may be added to the first metal routing layer Ml.

In the illustrated embodiment, the method 100 also includes a task 145 of placing the semiconductor cells to form the semiconductor integrated circuit, as illustrated, for example, in FIG. 5. In general, placement of the semiconductor cells is restricted based on the amount of metal routing layer M1 that exists in the semiconductor cells. Accordingly, if a majority of the semiconductor cells (e.g., from approximately 90% to approximately 99% of the semiconductor cells) are free of metal routing layer M1, a denser design can be achieved, the metal routing layer M1 can allow both pin access and routing, which creates less congestion at the pin access layer, better routability, and shorter wire lines (creating better performance and power), and the designer has full freedom to add as much power or less power based on the application (i.e., less dependency on the power added on the metal routing layer M1 inside the semiconductor cell).

In the illustrated embodiment, after the design layout is finalized, the method 100 may include a task 150 of taping out the final layout (i.e., the graphic for the photomask of the semiconductor integrated circuit is sent to the fabrication facility). The task 150 of taping out the final layout may include a task of outputting, by the PnR tool, a final GDSII or other suitable file format for production of the photomasks including real pin 205 shapes and pin-access vias 207. Additionally, in one or more embodiments, the method may include a task of fabricating a semiconductor die to form the integrated circuit and one or more packing and assembly tasks to produce a finished semiconductor chip.

In one or more embodiments, the methods 100 of the present disclosure may be performed by and/or utilizing computer-executable instructions (e.g., electronic design automation (EDA) software) stored in a non-volatile memory device which, when executed by a processor, cause the processor to perform the tasks described above. Additionally, the tasks described above may including displaying the layout of the semiconductor cell (e.g., the layout of the shadow pin regions) and the semiconductor integrated circuit on a display. The term “processor” is used herein to include any combination of hardware, firmware, and software, employed to process data or digital signals. The hardware of a processor may include, for example, application specific integrated circuits (ASICs), general purpose or special purpose central processors (CPUs), digital signal processors (DSPs), graphics processors (GPUs), and programmable logic devices such as field programmable gate arrays (FPGAs). In a processor, as used herein, each function is performed either by hardware configured, i.e., hard-wired, to perform that function, or by more general purpose hardware, such as a CPU, configured to execute instructions stored in a non-transitory storage medium. A processor may be fabricated on a single printed wiring board (PWB) or distributed over several interconnected PWBs. A processor may contain other processors; for example a processor may include two processors, an FPGA and a CPU, interconnected on a PWB.

While this invention has been described in detail with particular references to embodiments thereof, the embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention.

What is claimed is:

1. A computer-implemented method comprising:
generating a layout of a semiconductor cell, the layout comprising:
a plurality of semiconductor devices;
intra-cell connections between the plurality of semiconductor devices, the intra-cell connections comprising power rails; and
a plurality of shadow pin regions for placement of a plurality of pins by a placement and routing tool, each shadow pin region of the plurality of shadow pin regions defining a maximum legal boundary that each pin of the plurality of pins may occupy without violating ground rules.

2. The method of claim 1, wherein the layout further comprises the plurality of pins in the plurality of shadow pin regions, wherein the plurality of pins are placed by the placement and routing tool.

3. The method of claim 2, wherein the layout further comprises a plurality of access vias on the plurality of pins, wherein the plurality of access vias are placed by the placement and routing tool.

4. The method of claim 3, further comprising generating a layout of a semiconductor integrated circuit, the layout of the semiconductor integrated circuit comprising:
a plurality of instances of the semiconductor cell; and
routing metal layers connected to the plurality of pins by the plurality of access vias, wherein the routing metal layers are placed with the placement and routing tool.

5. The method of claim 2, wherein at least one pin of the plurality of pins is smaller than a corresponding shadow pin region of the plurality of shadow pin regions.

6. The method of claim 2, wherein at least one pin of the plurality of pins is substantially a same size as a corresponding shadow pin region of the plurality of shadow pin regions.

7. The method of claim 1, wherein the plurality of shadow pin regions is on a routing grid.

8. The method of claim 1, wherein the plurality of shadow pin regions is not on a routing grid.

9. The method of claim 1, wherein the layout further comprises at least one blockage region.

10. The method of claim 1, wherein at least one shadow pin region of the plurality of shadow pin regions is a 1D structure.

11. The method of claim 1, wherein at least one shadow pin region of the plurality of shadow pin regions is a 2D structure.

12. The method of claim 1, wherein the plurality of shadow pin regions are associated with a metal layer of the semiconductor cell selected from the group consisting of metal layer Mint, metal layer M0, metal layer M1, and metal layer M2.

13. The method of claim 1, wherein the layout further comprises power staples or power stripes.

14. The method of claim 13, wherein the power staples comprise a pair of double power staples.

15. The method of claim 2, wherein at least two pins of the plurality of pins are aligned.

16. The method of claim 2, wherein at least two pins of the plurality of pins are staggered.

17. A non-transitory computer readable medium having instructions stored therein which, when executed by a processor, cause the processor to:
generate a layout for a semiconductor cell, the layout comprising:
a plurality of semiconductor devices;
intra-cell connections between the plurality of semiconductor devices, the intra-cell connections comprising power rails; and
a plurality of shadow pin regions for placement of a plurality of pins by a placement and routing tool, each shadow pin region of the plurality of shadow pin regions defining a maximum legal boundary that each pin of the plurality of pins may occupy without violating ground rules.

18. The non-transitory computer readable medium of claim 17, wherein the instructions, when executed by the processor, further cause the processor to place the plurality of pins within the shadow pin regions.

19. The non-transitory computer readable medium of claim 18, wherein the instructions, when executed by the processor, further cause the processor to generate a layout for a semiconductor integrated circuit, the layout for the semiconductor integrated circuit comprising a series of instances of the semiconductor cell and interconnections between the plurality of instances of the semiconductor cell.
